(19) United States
(12) Patent Application Publication
(10) Pub. No.: US 2011/0049597 A1
(43) Pub. Date: Mar. 3, 2011

(54) NON-VOLATILE MEMORY DEVICE

(75) Inventors: Ji-hong KIM, Changwon-city (KR); Kee-won KWON, Suwon-city (KR)

(73) Assignees: SAMSUNG TECHWIN CO., LTD., Changwon-city (KR); SUNGKYUNKWAN UNIVERSITY FOUNDATION FOR CORPORATE COLLABORATION, Suwon-city (KR)

(21) Appl. No.: 12/751,749

(22) Filed: Mar. 31, 2010

(30) Foreign Application Priority Data
Aug. 31, 2009 (KR) 10-2009-0081500

(51) Int. Cl. H01L 27/115; H01L 29/792

(52) U.S. Cl. 257/298; 257/314; 257/E29.309; 257/E27.103

(57) ABSTRACT

A non-volatile memory device including two or more capacitors having different sizes formed in separated regions and operating at a low voltage, the non-volatile memory device including: a conductive semiconductor substrate formed of a first conductive material; a conductive separation layer provided on at least one portion of the first conductive semiconductor substrate and formed of a second conductive material different from the first conductive material, and which separates an inside of the first conductive semiconductor substrate into a first region and a second region; an insulation layer provided on the first region and the second region to contact the first region and the second region; a charge storage layer provided on the insulation layer; a control gate electrically connected to the first region; and a data line electrically connected to the second region.

### CROSS-REFERENCE TO RELATED PATENT APPLICATION

This application claims the benefit of Korean Patent Application No. 10-2009-0081500, filed on Aug. 31, 2009 in the Korean Intellectual Property Office, the disclosure of which is incorporated herein in its entirety by reference.

### BACKGROUND

1. Field

Aspects of the exemplary embodiments relate to a non-volatile memory device capable of operating at a low voltage.

2. Description of the Related Art

When power supply to a non-volatile semiconductor memory device is stopped, memory data is maintained in the non-volatile memory device. Small-sized portable electronic products, such as portable multimedia reproduction devices, digital cameras, personal digital assistants (PDA), etc., are increasingly in demand and thus mass storage and high integration of non-volatile semiconductor memory devices are rapidly in progress. Such non-volatile semiconductor memory devices are classified into programmable read only memory (PROM), erasable PROM (EPROM), and electrically EPROM (EEPROM). Furthermore, flash memory devices are exemplary memory devices.

Flash memory devices perform an erasing operation and a rewriting operation in a block unit, and are able to achieve high integration and maintain data. Thus, flash memory devices are not only substituted as main memory devices in a system, but are also applied to a general dynamic random access memory (DRAM) interface. Also, flash memory devices can achieve high integration and mass storage and reduce manufacturing costs, and thus can be substituted as auxiliary storage devices, such as a hard disk drive.

A tunneling insulation layer having a thickness of about 7 nm, a charge storage layer, a blocking insulation layer having a thickness of about 13 nm, and a control gate are sequentially stacked in a memory cell included in a flash memory device formed on a semiconductor substrate. Flash memory devices perform a wiring operation by a hot electron injection or Fowler-Nordheim (F-N) tunneling, and perform an erasing operation by F-N tunneling.

In this regard, electrons are injected and erased by coupling a voltage applied to a control gate to the blocking insulation layer, changing a voltage of the charge storage layer, and generating a tunneling current through a thin tunneling insulation layer. When flash memory devices use insulation layers having thicknesses of about 7 nm and 13 nm for tunneling oxide and coupling oxide, respectively, a high voltage of about 20 V is applied to a control gate or a semiconductor substrate in order to perform writing and erasing operations. Flash memory devices must include a new type of transistor having a thick insulation layer capable of enduring a high voltage, which increases manufacturing complexity and expense.

The characteristics of flash memory cells vary according to a thickness of a tunneling insulator (35 nm in 30 nm technology node), an area of a charge storage layer and a semiconductor substrate, an area of the charge storage layer and a control gate, and/or a thickness of a blocking insulation layer. The core characteristics of flash memory cells include a programming speed, an erasing speed, a distribution of program cells, and/or a distribution of erasure cells. Also, the reliability characteristics of flash memory cells include program and erasure endurance and data retention.

FIG. 5 is a graph illustrating a voltage applied to a control gate of a related art non-volatile memory device with respect to a current. Referring to FIG. 5, the volume of a leakage current that flows through an insulation layer having the same thickness as a thickness of 7.0 nm of a tunneling insulation layer is changed to an axis indicating the tunneling characteristics. A straight line indicates the F-N tunneling characteristics in a section between about 7.8 V and about 9.4 V, which is a voltage section used for inducing tunneling. The leakage current flows in the insulation layer having a thickness of 7 nm, and thus a voltage higher than 7 V is not applied to the insulation layer in order to avoid a tunneling current.

### SUMMARY

Exemplary embodiments provide a non-volatile memory device including two or more capacitors having different sizes formed in separated regions and operating at a low voltage.

According to an aspect of an exemplary embodiment, there is provided a non-volatile memory device including: a conductive semiconductor substrate which is formed of a first conductive material; a second conductive separation layer which is disposed on at least one portion of the conductive semiconductor substrate and formed of a second conductive material different from the first conductive material, and separates an inside of the first conductive semiconductor substrate into a first region and a second region; an insulation layer which is disposed on the first region and the second region to contact the first region and the second region; a charge storage layer which is disposed on the insulation layer; a control gate electrically connected to the first region; and a data line electrically connected to the second region.

The second conductive separation layer may include: a base layer which is disposed on a lower portion of the conductive semiconductor substrate; and a side wall surrounding the first region and the second region of the conductive semiconductor substrate, wherein the base layer surrounds the first region and the second region of the conductive semiconductor substrate.

A greater portion of the insulation layer disposed between the conductive semiconductor substrate and the charge storage layer may be disposed in the first region than the second region.

According to an aspect of another exemplary embodiment, there is provided a non-volatile memory device including: a conductive semiconductor substrate; a separation layer which is disposed on at least one portion of the conductive semiconductor substrate, and separates an inside of the conductive semiconductor substrate into a first region and a second region; an insulation layer which is disposed on the first region and the second region to contact the first region and the second region; a charge storage layer which is disposed on the insulation layer; a control gate electrically which is connected to the first region; and a data line which is electrically connected to the second region.

The separation layer may include: a base layer provided on a lower portion of the conductive semiconductor substrate; and a side wall surrounding the first region and the second region of the conductive semiconductor substrate, wherein the base layer surrounds the first region and the second region of the conductive semiconductor substrate.

The base layer and/or the side wall may be formed of an insulation material.

The base layer and the side wall may be formed of an insulation material.

The base layer and/or the side wall may be formed of a second conductive material different from a first conductive material that forms the conductive semiconductor substrate.

A greater portion of the insulation layer disposed between the conductive semiconductor substrate and the charge storage layer may be disposed in the first region than the second region.

According to an aspect of another exemplary embodiment, there is provided a non-volatile memory device including: a conductive semiconductor substrate which is formed of a first conductive material; a base layer which is disposed on a lower portion of the conductive semiconductor substrate; a separation layer including a side wall surrounding the first region and the second region of the conductive semiconductor substrate, wherein the base layer surrounds the first region and the second region of the conductive semiconductor substrate; an insulation layer which is disposed on the first region and the second region to contact the first region and the second region; a charge storage layer which is disposed on the insulation layer; a control gate electrically connected to the first region; and a data line electrically connected to the second region, wherein the base layer and the side wall are formed of a second conductive material different from the first conductive material.

According to an aspect of yet another exemplary embodiment, there is provided a non-volatile memory device including: a conductive semiconductor substrate which is formed of a first conductive material; a base layer which is disposed on a lower portion of the conductive semiconductor substrate; a separation layer including a side wall surrounding the first region and the second region of the conductive semiconductor substrate, wherein the base layer surrounds the first region and the second region of the conductive semiconductor substrate; an insulation layer which is disposed on the first region and the second region to contact the first region and the second region; a charge storage layer which is disposed on the insulation layer; a control gate which is electrically connected to the first region; and a data line which is electrically connected to the second region, wherein the base layer is formed of a second conductive material different from the first conductive material, and the side wall is formed of an insulation material.

According to an aspect of another exemplary embodiment, there is provided a non-volatile memory device including: a conductive semiconductor substrate which is formed of a first conductive material; a base layer which is disposed on a lower portion of the conductive semiconductor substrate; a separation layer including a side wall surrounding the first region and the second region of the conductive semiconductor substrate, wherein the base layer surrounds the first region and the second region of the conductive semiconductor substrate; an insulation layer which is disposed on the first region and the second region to contact the first region and the second region; a charge storage layer which is disposed on the insulation layer; a control gate which is electrically connected to the first region; and a data line which is electrically connected to the second region, wherein the base layer is formed of an insulation material, and the side wall is formed of a second conductive material different from the first conductive semiconductor material.

According to an aspect of another exemplary embodiment, there is provided a non-volatile memory device including: a conductive semiconductor substrate; a base layer which is disposed on a lower portion of the conductive semiconductor substrate; a separation layer including a side wall surrounding the first region and the second region of the conductive semiconductor substrate, wherein the base layer surrounds the first region and the second region of the conductive semiconductor substrate; an insulation layer which is disposed on the first region and the second region to contact the first region and the second region; a charge storage layer which is disposed on the insulation layer; a control gate which is electrically connected to the first region; and a data line which is electrically connected to the second region, wherein the base layer and the side wall are formed of an insulation material.

### BRIEF DESCRIPTION OF THE DRAWINGS

The above and other aspects will become more apparent by describing in detail exemplary embodiments with reference to the attached drawings in which:

FIG. 1 is a schematic cross-sectional view illustrating a non-volatile memory device according to an exemplary embodiment;

FIG. 2 is a schematic perspective view illustrating the non-volatile memory device of FIG. 1 according to an exemplary embodiment;

FIG. 3 is an equivalent circuit diagram of the non-volatile memory device of FIG. 1 according to an exemplary embodiment;

FIG. 4 is a circuit diagram of a level shifter capable of distributing voltages applied to a control gate node and a data line node according to an exemplary embodiment; and

FIG. 5 is a graph illustrating a voltage applied to a control gate of a related art non-volatile memory device with respect to a current.

### DETAILED DESCRIPTION OF THE EXEMPLARY EMBODIMENTS

Exemplary embodiments will now be described more fully with reference to the accompanying drawings. The inventive concept may, however, be embodied in many different forms and should not be construed as being limited to the exemplary embodiments set forth herein; rather, these exemplary embodiments are provided so that this disclosure will be thorough and complete, and will fully convey the concept of the invention to those of ordinary skill in the art. In the drawings, the thicknesses of layers and regions are exaggerated for clarity. Throughout the drawings, like reference numerals refer to like elements.

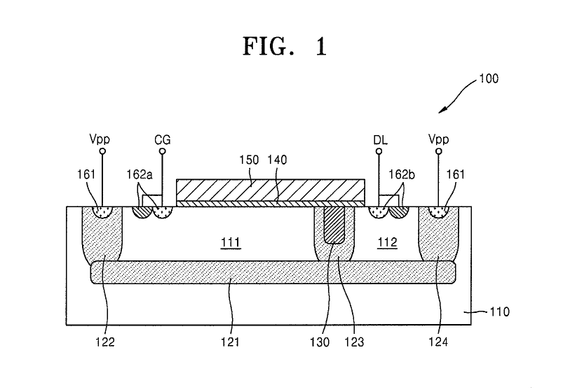

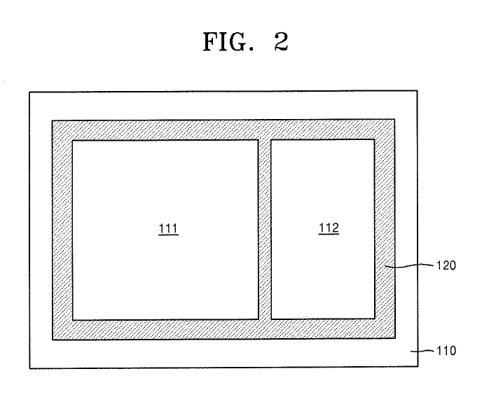

FIG. 1 is a schematic cross-sectional view illustrating a non-volatile memory device 100 according to an exemplary embodiment. FIG. 2 is a schematic perspective view illustrating the non-volatile memory device 100 according to an exemplary embodiment.

Referring to FIGS. 1 and 2, the non-volatile memory device 100 includes a substrate 110, a well region 120, a device separation layer 130, an insulation layer 140, a charge storage layer 150, and a control gate 162a.

The substrate 110 may be a semiconductor substrate and may include, for example, silicon, silicon-on-insulator, silicon-on-sapphire, germanium, silicon-germanium, or gallium-arsenide. The substrate 110 may be a p-type semiconductor substrate or an n-type semiconductor substrate. The substrate 110 includes the well region 120 that is formed by performing an ion implantation process and the device separation layer 130 that is formed by performing a shallow trench insulator (STI) process.

The well region 120 may be formed by injecting impurities having a conductive type opposite to that of the substrate 110. For example, if the substrate 110 is a p-type semiconductor substrate, the well region 120 may be formed by injecting n-type impurities. The n-type impurities may include all types of impurities capable of generating an electron as a main carrier. For example, the n-type impurities may include nitrogen (N), phosphorous (P), arsenic (As), antimony (Sb), and/or bismuth (Bi) that are included in the group V of the period table of elements. In contrast, if the substrate 110 is an n-type semiconductor substrate, the well region 120 may be formed by injecting p-type impurities. The p-type impurities may include all types of impurities capable of generating a hole as the main carrier. For example, the p-type impurities may include boron (B), aluminum (Al), gallium (Ga), indium (In), and/or thallium (Tl) that are included in the group III of the period table of elements.

The well region 120 includes first through fourth well regions 121 through 124. The first well region 121 may be formed in the lower portion of the substrate 110 and may be a base layer lower than the second through fourth well regions 122-124. The first through fourth well regions 121-124 may be side walls that surround a first region 111 and a second region 112 of the substrate 110 that are also surrounded by the first well region 121.

The first well region 121 and at least one selected from the group including the second through fourth well regions 122-124 may be substituted as an insulation layer. Alternatively, the first through fourth well regions 121-124 may be substituted as insulation layers.

The substrate 100 is separated into the first region 111 and the second region 112 by the first through fourth well regions 121-124. The first region 111 of the substrate 100 is formed by the first through third well regions 121-123. The second region 112 of the substrate 100 is formed by the first well region 121, the third well region 123, and the fourth well region 124.

The first region 111 of the substrate 100 may be greater than the second region 112. For example, the first region 111 may be ten times greater than the second region 112. A higher voltage of the charge storage layer 150 is applied to the first region 111 that is greater than the second region 112 than a voltage applied to the second region 112, and thus the third well region 123 may include the device separation layer 130 in order to increase the insulation effect of the first region 111 and the second region 112.

The insulation layer 140 may be formed on the first region 111 and the second region 112 of the substrate 110 to contact the first region 111 and the second region 112. A greater portion of the insulation layer 140 disposed between the substrate 100 and the charge storage layer 150 may be formed on the first region 111 than the second region 112. The insulation layer 140 may be formed by using a dry oxidation method or a wet oxidation method. For example, according to the wet oxidation method, when the insulation layer 140 is formed by performing a wet oxidation process at a temperature between 700° C. and 800° C. and performing an annealing operation for 20 to 30 minutes in a nitrogen atmosphere at a temperature of about 900° C. The insulation layer 140 may be a single layer or multiple layers including silicon oxide SiO₂, silicon nitride Si₃N₄, silicon oxide-nitride SiON, hafnium oxide HfO₂, hafnium silicon oxide HfSiₓO_{y}, aluminum oxide Al₂O₃, and/or zirconium oxide ZrO₂.

The charge storage layer 150 is formed on the insulation layer 140. The charge storage layer 150 may be a floating gate (FG) or a charge trap layer. If the charge storage layer 150 is the FG, the charge storage layer 150 may be a conductor including doped polysilicon or metal.

A Vpp region 161 that is a high density impurity region, a control gate (CG) region 162a, and a data line (DL) region 162b are formed on areas of the substrate 110 that are spaced from the insulation layer 140 and the charge storage layer 150 in order to connect the Vpp region 161, the CG region 162a, and the DL region 162b to a high static voltage of 7 V Vpp, a CG, and a DL, respectively.

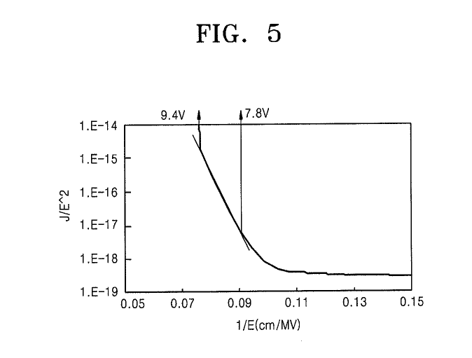

When an electron is injected into the charge storage layer 150, a voltage +7 V and a voltage −3 V are applied to the CG and the DL, respectively. When the electron is removed from the charge storage layer 150, the voltage +7 V and the voltage −3 V are applied to the DL and the CG, respectively. Thus, a high voltage of ±9 V is applied to the charge storage layer 150, which generates a tunneling current as described with reference to FIG. 5. However, the non-volatile memory device 100 according to aspects of the present inventive concept operates according to a general complimentary metal oxide semiconductor (CMOS) process since the non-volatile memory device 100 does not need the insulation layer 140 having a thickness greater than 7 nm by using a level shifter circuit that separately drives the voltages of +7 V and −3 V.

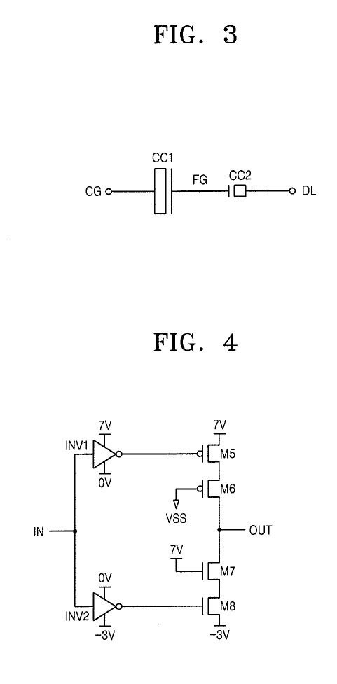

FIG. 3 is an equivalent circuit diagram of the non-volatile memory device 100 according to an exemplary embodiment. Referring to FIG. 3, the non-volatile memory device 100 includes a first cell capacitor CC1 and a second cell capacitor CC2 as non-volatile memory cells.

The first cell capacitor CC1 is a memory cell including a capacitor formed in the first region 111. The second cell capacitor CC2 is a memory cell including a capacitor formed in the second region 112.

Since the first cell capacitor CC1 is greater than the second cell capacitor CC2 (for example, 10 or more times greater), the voltage of the FG (i.e., the charge storage layer 150 of FIG. 1) follows the voltage of the control gate (CG) node 162a. For example, if the voltages of +7 V and −3 V are applied to the CG node 162a and the data line (DL) node 162b, respectively, a voltage of about 6V is applied to the FG.

With regard to the operation of injecting electrons into the charge storage layer 150, if the voltages of +7 V and −3 V are applied to the CG node and the DL node, respectively, a voltage higher than 9 V is applied to both ends of the second cell capacitor CC2 so that many electrons are tunneled into the FG through the insulation layer 140 (meaning that positive charges are discharged). A voltage of the charge storage layer 150 is reduced according to the tunneling of electrons, which makes it difficult to tunnel electrons into the second cell capacitor CC2 and thus the voltage of the charge storage layer 150 is reduced to about 4 V. Thereafter, if the voltages applied to the CG node and the DL node are removed, a voltage of −2 V remains in the FG.

With regard to an erasure operation, if voltages of −3 V, 7 V, and 7 V are applied to the CG node, the DL node, and the FG node, respectively, a voltage of about 9 V is applied in an opposite direction to both ends of the second cell capacitor CC2, and thus electrons are discharged from the FG (meaning that positive charges are accumulated). Thus, the voltage of the charge storage layer 150 is increased to 0 V. If the voltages applied to the CG node and the DL are removed, the voltage of the charge storage layer 150 is increased to 2 V. Information about the memory cells is determined according to whether the voltage of the FG is high or low.

FIG. 4 is a circuit diagram of a level shifter capable of distributing voltages applied to the CG node and the DL node of FIG. 3 according to an exemplary embodiment. Referring to FIG. 4, the level shifter includes a first inverter INV1, a second inverter INV2, and fifth through eighth transistors M5-M8. The fifth and sixth transistors M5 and M6 are P-type transistors. The seventh and eighth transistors M7 and M8 are N-type transistors.

If a high voltage (1.8 V) is input IN into the level shifter, the first inverter INV1 and the second inverter INV2 are in a low state, the fifth through seventh transistors M5-M7 are turned on, and the eighth transistor M8 is turned off so that the level shifter outputs OUT a voltage of 7 V. If a low voltage (0 V) is input IN into the level shifter, the first inverter INV1 and the second inverter INV2 are in a high state, the sixth through eighth transistors M6-M8 are turned on, and the fifth transistor M5 is turned off so that the level shifter outputs OUT a voltage of −3 V.

The level shifter uses a voltage of 1.8 V supplied to VDD to generate a level shifted signal that drives between voltages of 0 and 7 V and −3 V and 0. If the level shifted signal is connected to the fifth through eighth transistors M5-M8 in serial, a voltage greater than 7 V is not applied to the fifth through eighth transistors M5-M8. Thus, the level shifter shifts an output value between voltages of −3 V and 7 V.

While exemplary embodiments have been particularly shown and described, it will be understood by those of ordinary skill in the art that various changes in form and details may be made therein without departing from the spirit and scope of the inventive concept as defined by the appended claims. The exemplary embodiments should be considered in a descriptive sense only and not for purposes of limitation. Therefore, the scope of the claims is defined not by the detailed description of the exemplary embodiments but by the appended claims.

What is claimed is:

1. A non-volatile memory device comprising:
a conductive semiconductor substrate which is formed of a first conductive material;
a conductive separation layer which is formed of a second conductive material different from the first conductive material and disposed on at least one portion of the conductive semiconductor substrate, and which separates an inside of the conductive semiconductor substrate into a first region and a second region;
an insulation layer which is disposed on the first region and the second region to contact the first region and the second region;
a charge storage layer which is disposed on the insulation layer;
a control gate which is electrically connected to the first region; and
a data line which is electrically connected to the second region.

2. The non-volatile memory device of claim 1, wherein the conductive separation layer comprises:
a base layer which is disposed on a lower portion of the conductive semiconductor substrate and surrounds the first region and the second region of the conductive semiconductor substrate; and
a side wall which surrounds the first region and the second region of the conductive semiconductor substrate.

3. The non-volatile memory device of claim 1, wherein a larger portion of the insulation layer disposed between the conductive semiconductor substrate and the charge storage layer is disposed on the first region than the second region.

4. The non-volatile memory device of claim 1, wherein an area of the first region is greater than an area of the second region.

5. The non-volatile memory device of claim 4, further comprising:
a first cell capacitor which is a non-volatile memory cell in the first region; and
a second cell capacitor which is a non-volatile memory cell in the second region,
wherein the first cell capacitor is larger than the second cell capacitor.

6. The non-volatile memory device of claim 1, wherein the insulation layer has a thickness less than or equal to 7.0 nm, and a voltage greater than 7.0 V is applied to the charge storage layer to generate a tunnel current.

7. The non-volatile memory device of claim 6, wherein ±9 V is applied to the charge storage layer.

8. The non-volatile memory device of claim 6, wherein the control gate and the data line are separately applied respective voltages when an electron is injected or removed from the charge storage layer.

9. The non-volatile memory device of claim 1, wherein the first conductive material is a conductive type opposite to that of the second conductive material.

10. The non-volatile memory device of claim 9, wherein the first conductive material is formed of n-type impurities and the second conductive material is formed of p-type impurities, or the second conductive material is formed of n-type impurities and the first conductive material is formed of p-type impurities.

11. A non-volatile memory device comprising:
a conductive semiconductor substrate;
a separation layer which is disposed on at least one portion of the first conductive semiconductor substrate, and separates an inside of the conductive semiconductor substrate into a first region and a second region;
an insulation layer which is disposed on the first region and the second region to contact the first region and the second region;
a charge storage layer which is disposed on the insulation layer;
a control gate which is electrically connected to the first region; and
a data line which is electrically connected to the second region.

12. The non-volatile memory device of claim 11, wherein the separation layer comprises:
a base layer which is disposed on a lower portion of the conductive semiconductor substrate and surrounds the first region and the second region of the conductive semiconductor substrate; and
a side wall which surrounds the first region and the second region of the conductive semiconductor substrate.

13. The non-volatile memory device of claim 12, wherein at least one of the base layer and the side wall is formed of an insulation material.

14. The non-volatile memory device of claim 12, wherein the base layer and the side wall are each formed of an insulation material.

15. The non-volatile memory device of claim 12, wherein:
the conductive semiconductor substrate is formed of a first conductive material; and
at least one of the base layer and the side wall is formed of a second conductive material different from the first conductive material.

16. The non-volatile memory device of claim 11, wherein a greater portion of the insulation layer disposed between the conductive semiconductor substrate and the charge storage layer is disposed on the first region than the second region.

17. A non-volatile memory device comprising:
a conductive semiconductor substrate which is formed of a first conductive material;
a base layer which is disposed on a lower portion of the conductive semiconductor substrate;
a separation layer comprising a side wall which separates an inside of the conductive semiconductor substrate into a first region and a second region, and surrounds the first region and the second region;
an insulation layer which is disposed on the first region and the second region to contact the first region and the second region;
a charge storage layer which is disposed on the insulation layer;
a control gate which is electrically connected to the first region; and
a data line which is electrically connected to the second region,
wherein the base layer surrounds the first region and the second region of the conductive semiconductor substrate, and the base layer and the side wall are formed of a second conductive material different from the first conductive material.

18. A non-volatile memory device comprising:
a conductive semiconductor substrate which is formed of a first conductive material;
a base layer which is disposed on a lower portion of the conductive semiconductor substrate;
a separation layer comprising a side wall which separates an inside of the conductive semiconductor substrate into a first region and a second region, and surrounds the first region and the second region;
an insulation layer which is disposed on the first region and the second region to contact the first region and the second region;
a charge storage layer which is disposed on the insulation layer;
a control gate which is electrically connected to the first region; and
a data line which is electrically connected to the second region,
wherein the base layer surrounds the first region and the second region of the conductive semiconductor substrate, the base layer is formed of a second conductive material different from the first conductive material, and the side wall is formed of an insulation material.

19. A non-volatile memory device comprising:
a conductive semiconductor substrate which is formed of a first conductive material;
a base layer which is disposed on a lower portion of the conductive semiconductor substrate;
a separation layer comprising a side wall which separates an inside of the conductive semiconductor substrate into a first region and a second region and surrounds the first region and the second region;
an insulation layer which is disposed on the first region and the second region to contact the first region and the second region;
a charge storage layer which is disposed on the insulation layer;
a control gate which is electrically connected to the first region; and
a data line which is electrically connected to the second region,
wherein the base layer surrounds the first region and the second region of the conductive semiconductor substrate, the base layer is formed of an insulation material, and the side wall is formed of a second conductive material different from the first conductive material.

20. A non-volatile memory device comprising:
a conductive semiconductor substrate;
a base layer which is disposed on a lower portion of the conductive semiconductor substrate;
a separation layer comprising a side wall which separates an inside of the conductive semiconductor substrate into a first region and a second region and surrounds the first region and the second region;
an insulation layer which is disposed on the first region and the second region to contact the first region and the second region;
a charge storage layer which is disposed on the insulation layer;
a control gate which is electrically connected to the first region; and
a data line which is electrically connected to the second region,
wherein the base layer surrounds the first region and the second region of the conductive semiconductor substrate and the base layer and the side wall are each formed of an insulation material.

21. A non-volatile memory device comprising:
a conductive semiconductor substrate;
a separation layer which separates an inside of the conductive semiconductor substrate into a first region and a second region;
an insulation layer which is disposed on the first region and the second region to contact the first region and the second region;
a charge storage layer which is disposed on the insulation layer;
a control gate which is electrically connected to the first region;
a data line which is electrically connected to the second region;
a first cell capacitor which is a non-volatile memory cell in the first region; and
a second cell capacitor which is a non-volatile memory cell in the second region,
wherein the first cell capacitor is larger than the second cell capacitor.
